(19) United States
(12) Patent Application Publication
(10) Pub. No.: US 2020/0328310 A1
(43) Pub. Date: Oct. 15, 2020

(54) THIN FILM TRANSISTOR AND ARRAY SUBSTRATE

(71) Applicants: BOE TECHNOLOGY GROUP CO., LTD., Beijing (CN); Peking University, Beijing (CN)

(72) Inventors: Hu Meng, Beijing (CN); Xuelei Liang, Beijing (CN); Jiye Xia, Beijing (CN); Qi Huang, Beijing (CN)

(21) Appl. No.: 16/304,126

(22) PCT Filed: Mar. 11, 2018
(86) PCT No.: PCT/CN2018/078649

§ 371 Date: Nov. 21, 2018

(30) Foreign Application Priority Data
Mar. 17, 2017 (CN) 201710161372.6

(51) Int. Cl. H01L 29/786

(52) U.S. Cl. CPC H01L 29/78618; H01L 29/78612

(57) ABSTRACT

The present disclosure provides a thin film transistor and an array substrate. The thin film transistor includes a source, a drain, and an active layer, and the thin film transistor further includes a blocking layer between the active layer and the source and/or the drain. The present disclosure can reduce the off-state current of the thin film transistor and suppress the bipolar effect.

### CROSS-REFERENCE TO RELATED APPLICATIONS

The present application is based on International Application No. PCT/CN2018/078649, filed on Mar. 11, 2018, which claims priority to Chinese Patent Application No. 201710161372.6, filed on Mar. 17, 2017, the entire contents thereof are incorporated herein by reference.

### TECHNICAL FIELD

The present disclosure relates to the technical field of thin film transistor, and in particular, to a thin film transistor and an array substrate.

### BACKGROUND

Due to its excellent electrical properties, good thermal conductivity and good mechanical strength, carbon nanotubes have been widely used in various fields such as display, sensors, RF (Radio Frequency) circuits, flexible circuits, showing great application potential. In the case that the carbon nanotube thin is used in the film transistor, the carbon nanotube is generally used as an active layer material, including carbon nanotubes in a shape of random network or in parallel arrangement as a channel film material. The carbon nanotube used as the active layer material is generally a semiconductor type carbon nanotube having a diameter generally ranging from 0.8 to 1.6 nm and a semiconductor band gap of about 0.5 to 1 eV. Due to the small band gap between carbon nanotubes and difficulty to make substitutional doping which is different from the situation that conventional semiconductors are used, the passivated bottom-gate thin film transistor or top-gate thin film transistor has a larger off-state current (10-100 pA) and exhibits a bipolar phenomenon of electron-and-hole conduction, which has the disadvantage to an application of the backplane in the display field.

In the related art, in order to suppress the off-state current and bipolar phenomenon of the carbon nanotube thin film transistor, there are the following solutions: (1) using a small-diameter carbon nanotube (Hipco, CoMocat, etc.) as the active layer material to construct the thin film transistor; (2) using molecular adsorption to carry out charge transfer with the surface of the carbon nanotube to form doping of the carbon nanotube.

Therefore, there is still room for improvement in the technical solutions in the related art.

It should be noted that the information disclosed in the background section above is only intended to enhance understanding of the background of the present disclosure, and thus may include information that does not constitute prior art known to those of ordinary skill in the art.

### SUMMARY

The present disclosure provides a thin film transistor and an array substrate, thus at least to some extent overcoming one or more problems due to limitations and disadvantages of the related art.

Other features and advantages of the present disclosure will be apparent from the following detailed description, or may be learned in part by practice of the present disclosure.

According to an aspect of the present disclosure, there is provided a thin film transistor including a source, a drain and an active layer, the thin film transistor further including: a blocking layer provided between the active layer and the source and/or the drain.

In an exemplary arrangement of the present disclosure, the source and/or the drain are provided above the blocking layer, and the source and/or drain cover the blocking layer.

In an exemplary arrangement of the present disclosure, the blocking layer includes an electron blocking layer or a hole blocking layer, wherein the electron blocking layer is made of electron barrier material, and the hole blocking layer is made of hole barrier material.

In an exemplary arrangement of the present disclosure, the active layer includes a carbon nanotube, and a top of valence band of the electron barrier material is equal to a top of valence band of the carbon nanotube, and a bottom of conduction band of the electron barrier material and a bottom of conduction band of the carbon nanotube differ by a predetermined value.

In an exemplary arrangement of the present disclosure, the thin film transistor includes a base substrate, a gate of the thin film transistor provided on the base substrate, and a gate insulator covering the gate. The active layer is provided on the gate insulator. The blocking layer is provided on the active layer. The source and/or the drain are provided on the blocking layer.

In an exemplary arrangement of the present disclosure, material of the blocking layer is MoO₃.

In an exemplary arrangement of the present disclosure, the thin film transistor includes a base substrate, a gate insulator provided on the source and the drain, and a gate provided on the gate insulator. The active layer is provided on the base substrate. The blocking layer is provided on the active layer. The source and/or the drain are provided on the blocking layer.

In an exemplary arrangement of the present disclosure, material of the blocking layer is V₂O₅.

In an exemplary arrangement of the present disclosure, the source and the drain include metal.

According to an aspect of the present disclosure, there is provided an array substrate including the thin film transistor of any of the above arrangements.

The above general description and the following detailed description are intended to be illustrative and not restrictive of the present disclosure.

### BRIEF DESCRIPTION OF THE DRAWINGS

The accompanying drawings are incorporated in and constitute part of the specification, show the arrangements of the present disclosure and are intended to explain the principle of the present disclosure together with the description. It is apparent that the accompanying drawings in the following description are only some of the arrangements of the present disclosure, and other drawings may be obtained from these accompanying drawings by those skilled in the art without any creative work.

FIG. 1 is a structural schematic view showing a first thin film transistor in an exemplary arrangement of the present disclosure.

FIG. 2 is a schematic view showing a relationship between a top of valence band and a bottom of conduction band between a blocking layer and an active layer of a thin film transistor in an exemplary arrangement of the present disclosure.

FIG. 3 is a structural schematic view showing a second thin film transistor in an exemplary arrangement of the present disclosure.

FIG. 4 is a structural schematic view showing a third thin film transistor in an exemplary arrangement of the present disclosure.

FIG. 5 is a structural schematic view showing a fourth thin film transistor in an exemplary arrangement of the present disclosure.

FIG. 6 is a structural schematic view showing a fifth thin film transistor in an exemplary arrangement of the present disclosure.

FIG. 7 is a structural schematic view showing a sixth thin film transistor in an exemplary arrangement of the present disclosure.

FIG. 8 is a structural schematic view showing an array substrate corresponding to a structure of the thin film transistor shown in FIG. 1.

FIG. 9 is a structural schematic view showing a seventh thin film transistor in an exemplary arrangement of the present disclosure.

FIG. 10 is a structural schematic view showing an eighth thin film transistor in an exemplary arrangement of the present disclosure.

FIG. 11 is a structural schematic view showing a ninth thin film transistor in an exemplary arrangement of the present disclosure.

FIG. 12 is a structural schematic view showing another array substrate corresponding to a structure of the thin film transistor shown in FIG. 9.

### DETAILED DESCRIPTION

Example arrangements will now be described more fully with reference to the accompanying drawings. However, the example arrangements can be embodied in a variety of forms, and should not be construed as limitation of the examples set forth herein; the described features, structures, or characteristics may be combined in one or more arrangements in any suitable manner. In the following description, numerous specific details are provided in order to fully understand the arrangements of the present disclosure. However, those skilled in the art will appreciate that one or more of specific details may be omitted when technical solutions of the present disclosure is implemented, or other methods, components, devices, blocks, etc. may be employed.

It should be noted that, in the drawings, dimensions of layers and regions may be exaggerated for clarity of illustration. It should be also understood that, when an element or layer is referred to as being “on” another element or layer, it may be directly on the other element or an intermediate layer may be present therebetween. In addition, it should be understood that, when an element or layer is referred to as being “under” another element or layer, it may be directly under other elements or more than one intermediate layer or element may be present therebetween. In addition, it should also be understood that, when a layer or element is referred to as being “between” two layers or two elements, it may be a single layer between two layers or two elements, or more than one intermediate layer or element may be present. Like reference numbers indicate like elements throughout.

The technical solutions for suppressing an off-state current and a bipolar phenomenon of the carbon nanotube thin film transistor provided in the related arrangements of the present disclosure have certain disadvantages: (1) since a small-diameter carbon nanotube as an active layer is used, a contact barrier thereof with metal of a source or a drain increases so that it is difficult to form a good ohmic contact and the mobility of device will decrease significantly; (2) the molecular adsorption depends on a method of the surface adsorption, which has a poor performance stability without practicability.

Based on the above, an arrangement of the present disclosure first provides a thin film transistor (TFT) including a source, a drain and an active layer, wherein the thin film transistor may further include: a blocking layer provided between the active layer and the source and/or the drain. The arrangement of the present disclosure can greatly reduce the off-state current and suppress the bipolar effect of the thin film transistor by providing the blocking layer between the source and/or the drain and the active layer to block from contact between the active layer and the source and/or the drain.

The present disclosure is further described below in conjunction with specific arrangements, but the present disclosure is not limited to the following arrangements.

The thickness and the size and shape of an area of each film layer in the accompanying drawings do not reflect the true proportions of various components of the thin film transistor and the array substrate, and are merely intended to illustrate the present disclosure.

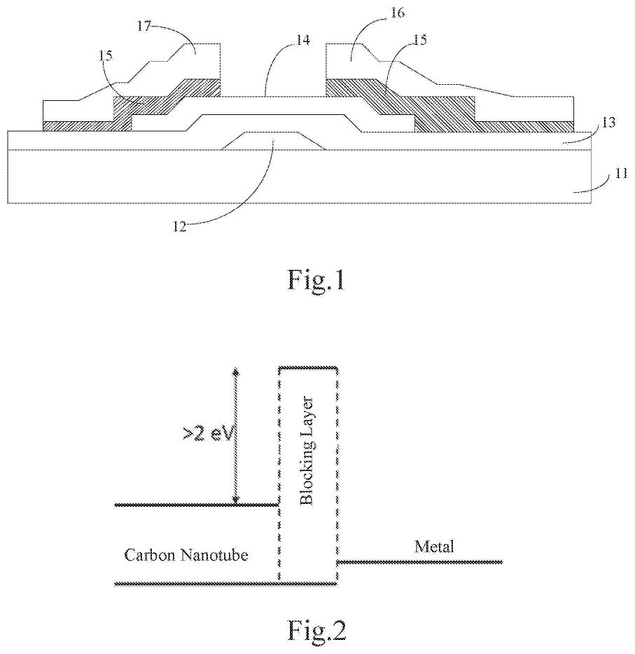

Here, the TFT manufactured in the arrangement of the present disclosure may be any one of a top gate TFT, a bottom gate TFT, or a double gate TFT. FIGS. 1-8 show a bottom gate TFT and FIGS. 9-12 show a top gate TFT as an example, but the present disclosure is not limited thereto.

FIG. 1 is a structural schematic view of a first thin film transistor in an exemplary arrangement of the present disclosure. The thin film transistor includes a base substrate 11, a gate 12 of the thin film transistor provided on the base substrate 11, a gate insulator 13 covering the gate 12, an active layer 14 provided on the gate insulator 13, a blocking layer 15 provided on the active layer 14 and a source 17 and a drain 16 provided on the blocking layer 15.

The base substrate 11 may be a flexible substrate such as a PET (polyethylene terephthalate) substrate, a PI (polyimide) substrate, or the like. Of course, it may be a hard substrate such as a glass substrate, a silicon oxide substrate, a silicon nitride substrate or the like.

In an exemplary arrangement, since a carbon nanotube (CNT) material has high mobility, the active layer 14 may be fabricated by using the carbon nanotube material. However, the present disclosure is not limited thereto. In addition to the CNT material, the active layer 14 may also be made of one-dimensional material such as a silicon nanowire or a III-V nanowire, and other structures having an overlapping structure, i.e., a semiconductor material with an X-type or Y-type structure.

The carbon nanotubes can be produced by the method for producing carbon nanotubes in the related art, and will not be described in detail herein. For example, a single-walled carbon nanotube powder prepared by an arc method (or a thermal plasma method, a laser ablation method) may be mixed with a polymer-containing toluene solution, dispersed, centrifuged, filtered, and then re-dispersed to obtain a solution of the single-walled carbon nanotubes with semiconductor type. Further, the active layer 14 of the thin film transistor in the arrangement of the present disclosure is produced by using the above solution of the carbon nanotubes.

The carbon nanotube provided by the arrangement of the present disclosure is mainly of a semiconductor type, and a value of the chirality index (n, m) satisfying (n−m)/3 is a non-integer. However, the present disclosure is not limited to a particular chirality.

In an exemplary arrangement, the source 17 and the drain 16 may include metal.

In the arrangement of the present disclosure, the metal may include at least one of noble metal such as palladium, gold or the like, or common metal such as chromium, nickel, copper or the like. However, the present disclosure is not limited thereto.

With reference to FIG. 1, both the source 17 and the drain 16 are provided on the blocking layer 15, and the source 17 and the drain 16 completely cover the blocking layer 15. A pattern of the blocking layer 15 may be the same as a pattern of the source 17 and the drain 16. However, the present disclosure is not limited thereto, as long as an orthographic projection of the blocking layer 15 on the base substrate 11 at least covers an orthographic projection of the source 17 and/or the drain 16 on the base substrate 11, thus blocking from contact between the active layer 14 and the source 17 and/or the drain 16 by the blocking layer 15.

In the arrangement shown in FIG. 1, the blocking layer 15 does not completely cover the active layer 14, i.e., it partially covers the active layer 14. However, the present disclosure is not limited thereto. In other arrangements, the blocking layer 15 is provided on the active layer 14 and covers the entire active layer 14 so that the blocking layer 15 may completely isolate the contact of the active layer 14 with the source 17 and the drain 16, which effectively reduces the off-state current and suppresses the bipolar phenomenon. In addition, the blocking layer spreads over the entire active layer 14, and the production of the film layer structure does not require an additional drawing process, thus simplifying the manufacturing process and improving performance of the film layer while the preparation efficiency is improved.

In an exemplary arrangement, the blocking layer 15 may include an electron blocking layer or a hole blocking layer, wherein the electron blocking layer is made of electron barrier material, and the hole blocking layer is made of hole barrier material. The blocking layer 15 of the arrangement of the present disclosure may be an electron blocking layer or a hole blocking layer disposed between the source 17 and/or the drain 16 metal and the active layer 14, in order to prevent the active layer 14 from directly contacting the metal to form thermal excitation injection of carriers and tunneling effect under the action of electric field caused by Schottky barrier and thus to form a leakage current, thus reducing the off-state current of the device and suppressing the bipolar effect.

In an exemplary arrangement, the electron barrier material and the hole barrier material may include an organic material or an inorganic material, an insulating material, or a semiconductor material such as Ta₂O₅, V₂O₅, MoO₃, WO₃, ZnO, or the like. A process such as ALD (Atomic Layer Deposition) is used to form a covering structure of the carbon nanotubes.

In the arrangement of the present disclosure, the material of the blocking layer 15 may be MoO₃. However, the present disclosure is not limited thereto.

In an exemplary arrangement, the blocking layer 15 may have a thickness ranging from 5 to 10 nm. However, the present disclosure is not limited thereto. The arrangement of the present disclosure may not introduce a large series resistance by controlling the thickness of the blocking layer, thus not affecting other electrical properties of the thin film transistor, and not affecting the electrical connection between the source/drain metal and the active layer, and simultaneously having sufficient blocking capability of carriers. In addition, the blocking layer having the above thickness can ensure that the thickness of the array substrate composed of the thin film transistor is not excessive.

FIG. 2 is a schematic view showing a relationship between a top of valence band and a bottom of conduction band between a blocking layer and an active layer of a thin film transistor in an exemplary arrangement of the present disclosure.

In the arrangement shown in FIG. 2, the top of valence band of the electron barrier material is approximately equal to the top of valence band of the carbon nanotube, and the bottom of conduction band of the electron barrier material and the carbon nanotube conduction band bottom differ by a predetermined value.

In an exemplary arrangement, the top of valence band of the electron barrier material and the top of valence band of the carbon nanotube are both about 5.0 eV.

In an exemplary arrangement, the predetermined value is greater than 2 eV. It should be noted that the predetermined value between the bottom of conduction band of the electron barrier material and the bottom of conduction band of the carbon nanotube may be in a range of values which is at least greater than 1 eV. With respect to the material in the exemplary arrangement, it is required that the predetermined value is greater than 2 eV to satisfy limitation of the transport capability of carriers.

The top of valence band of the electron blocking layer in the arrangement of the present disclosure is close to the top of valence band of the carbon nanotube (about 0.5 eV), and the bottom of conduction band thereof is very different from the bottom of conduction band of the carbon nanotube (Δ>2 eV), and the band structure has a certain asymmetrical structure, thus ensuring holes flow smoothly through the electron blocking layer while blocking electrons. In the case of an applied voltage, the hole barrier is easily overcome and the electron barrier remains at a large value, so that the hole current in the depleted state is lowered due to a certain hole barrier, and the current formed by electron conduction after the device inversion is significantly suppressed due to the high electron barrier.

With respect to the hole blocking layer, the top of conduction band thereof is close to the top of conduction band of the carbon nanotube, and the bottom of valence band thereof is greatly different from that of the carbon nanotube.

In other arrangements, when the blocking layer 15 is a hole blocking layer and the hole blocking layer is made of hole barrier material, the top of valence band of the hole barrier material is approximately equal to the top of valence band of the carbon nanotube and the bottom of conduction band of the hole barrier material and the bottom of conduction band of the carbon nanotube differ by a predetermined value. Thus, since the top of valence band of the designed hole blocking layer material is close to the top of valence band of the carbon nanotube, while the bottom of conduction band thereof and the bottom of conduction band of the carbon nanotube greatly differ, and the band structure has a certain asymmetry, thus ensuring electrons flow smoothly through the hole blocking layer while blocking holes.

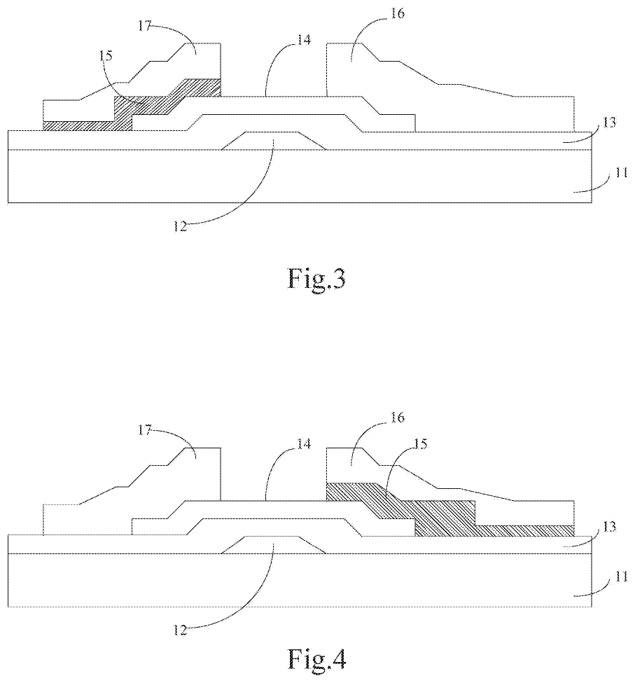

FIG. 3 is a structural schematic view showing a second thin film transistor in an exemplary arrangement of the present disclosure.

In the arrangement shown in FIG. 3, it is different from the thin film transistor shown in FIG. 1 in that only the source 17 is provided above the blocking layer 15, and the source 17 completely covers the portion of the blocking layer 15 that is in contact therewith. The drain 16 is in direct contact with the active layer 14 without the blocking layer 15 therebetween.

FIG. 4 is a structural schematic view showing a third thin film transistor in an exemplary arrangement of the present disclosure.

In the arrangement shown in FIG. 4, it is different from the thin film transistor shown in FIG. 1 in that only the drain 16 is provided above the blocking layer 15, and the drain 16 completely covers the portion of the blocking layer 15 that is in contact therewith. The source 17 is in direct contact with the active layer 14 without the blocking layer 15 therebetween.

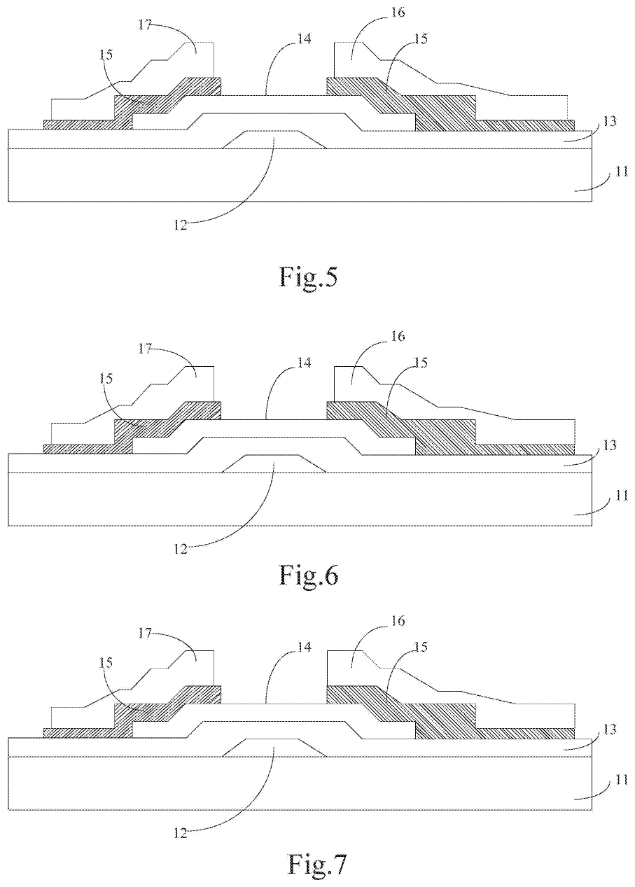

FIG. 5 is a structural schematic view showing a fourth thin film transistor in an exemplary arrangement of the present disclosure.

In the arrangement shown in FIG. 5, it is different from the thin film transistor shown in FIG. 1 in that although the source 17 and the drain 16 are simultaneously provided above the blocking layer 15, the source 17 and the drain 16 are provided to both partially cover the portion of the blocking layer 15 that is in contact therewith. Meanwhile, an orthographic projection of the lower surface of the drain 16 on the base substrate 11 is smaller than an orthographic projection of the upper surface of the portion of the blocking layer 15 in contact with the drain 16 on the base substrate 11, and both of front and rear sides of the drain 16 does not completely cover the blocking layer 15.

FIG. 6 is a structural schematic view showing a fifth thin film transistor in an exemplary arrangement of the present disclosure.

In the arrangement shown in FIG. 6, it is different from the thin film transistor shown in FIG. 1 in that although the source 17 and the drain 16 are simultaneously provided above the blocking layer 15, the source 17 and the drain 16 both partially cover the portion of the blocking layer 15 that is in contact therewith. At the same time, both of front and rear sides of the source 17 does not cover the blocking layer 15, the front side of the drain 16 does not completely cover the blocking layer 15, and the rear side of the drain 16 completely covers the blocking layer 15.

FIG. 7 is a structural schematic view showing a sixth thin film transistor in an exemplary arrangement of the present disclosure.

In the arrangement shown in FIG. 7, it is different from the thin film transistor shown in FIG. 1 in that although the source 17 and the drain 16 are simultaneously provided above the blocking layer 15, the source 17 does not completely cover the blocking layer 15, and only the drain 16 completely covers blocking layer 15.

It should be noted that although only the cases shown in FIG. 1, 3-7 is shown in the arrangements of the present disclosure, as long as the orthographic projection of the upper surface of the blocking layer on the base substrate 11 covers the orthographic projection of the lower surface of the source and/or the drain on the base substrate 11 in the present disclosure, those may be arbitrarily modified according to the above arrangement and the orthographic projection of the upper surface of the blocking layer on the base substrate 11 may be appropriately increased.

The thin film transistor of the present arrangement can be used as a switching thin film transistor of an array substrate display area, and can also be used as a functional thin film transistor at the periphery of display area (such as a GOA (Gate Driver on Array) circuit, ESD (Electro-Static discharge) circuit, etc.), which is suitable for various displays such as LCD (Liquid Crystal Display) and AMOLED (Active-matrix organic light emitting diode) or the like.

An arrangement of the present disclosure provides a structure of a carbon nanotube thin film transistor. By increasing an electron or hole barrier material between the source (or the drain) metal (or both the source metal and the drain metal) and the active layer, the off-state current is greatly reduced and the bipolar effect is suppressed. Compared with the related art, the method has the advantages of not changing the channel material, the stable performance and the simple process, etc.

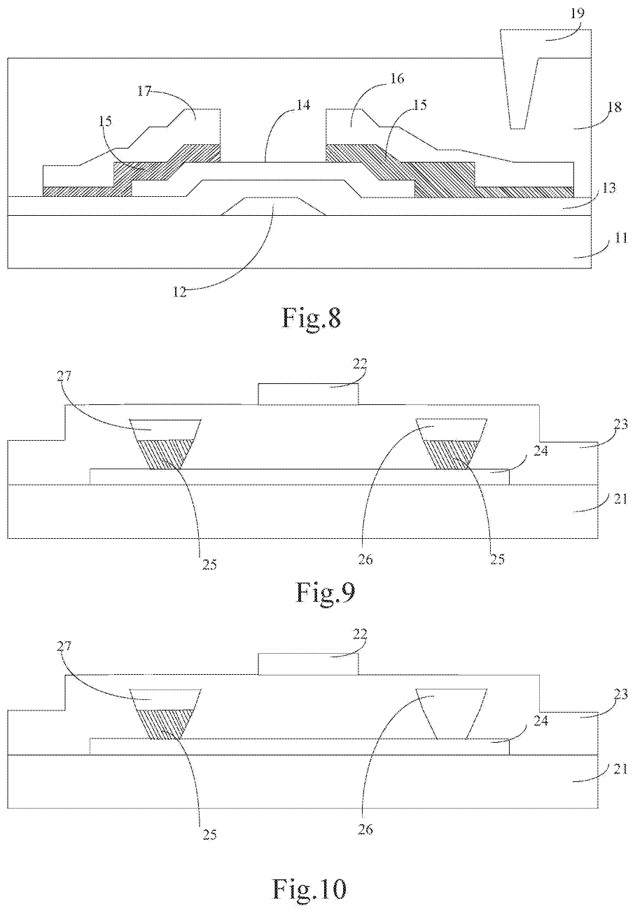

FIG. 8 is a structural schematic view showing an array substrate corresponding to a structure of the thin film transistor shown in FIG. 1.

Further, an arrangement of the present disclosure further provides an array substrate, including the thin film transistor described in any of the above arrangements. Since the principle for solving the problem of the array substrate is similar to that of the above-mentioned thin film transistor, the implementation of the array substrate may refer to the implementation of the above-mentioned thin film transistor, which will not be repeated.

Referring to FIG. 8, the array substrate may further include a passivation layer 18 and an electrode (for example, indium tin oxide (ITO) 19.

The technical solution of the present disclosure can be applied to various types of TFT array substrates, and the present disclosure does not limit the types of TFT elements in the TFT array substrate. For example, it may be any one of the following TFT element structures:

structure 1: a coplanar TFT in which a source/drain is disposed in the same layer as an active layer.

structure 2: a back channel etched TFT in which a source/drain is provided above the active layer.

structure 3: an etched blocking-type TFT further includes: an etch blocking layer provided above the active layer, the source/drain being electrically connected to the active layer through a via.

With the above three structures, the blocking layer according to the present disclosure may be disposed regardless of any type of the TFTs, thus effectively blocking the contact between the active layer and the drain/source, effectively reducing the off-state current and suppressing the bipolar effect.

A bottom gate thin film transistor and an array substrate according to an arrangement of the present disclosure will be described below with reference to a specific example.

A method for manufacturing a bottom gate structure carbon nanotube thin film transistor with MoO₃ having a thickness of 5-10 nm as electron blocking layer material of a blocking layer on a base substrate (taking a glass substrate as an example) includes the following blocks:

Block 1: cleaning the glass substrate according to a standard method;

a buffer layer may be formed on the glass substrate;

For example, SiO₂ film having a thickness of 200 nm may be deposited as the buffer layer by a method such as PECVD (Plasma Enhanced Chemical Vapor Deposition) or CVD (Chemical Vapor Deposition).

Block 2: depositing Mo (but the disclosure is not limited thereto) having thickness of for example 200 nm (thickness ranging from 2000 to 3000 angstroms) on the buffer layer by using sputter coating to form a gate of the thin film transistor;

Specifically, a gate conductive layer may be deposited on the buffer layer by sputtering to form a gate of the thin film transistor by a patterning process, and the gate conductive layer may be made of metal material such as Mo, Al, or Cr, alloy material or other composite conductive material.

Block 3: defining a gate region after photolithography and development, and then forming a gate layer through a wet etching process. In the process, the Mo layer is usually subjected to a wet etching process which has a low cost, but the disclosure is not limited thereto, and a suitable etching process may be selected according to metal characteristics of the specific gate, for example, RIE (Reactive Ion Etching) or ICP (Inductively Coupled Plasma) may be used.

Block 4: depositing insulating material such as silicon oxide (SiOx) or silicon nitride (SiNx) having a thickness of 100-200 nm by using PECVD to form a gate insulator;

For example, SiOx can be deposited as a gate insulator by a CVD method at 370° C.

Block 5: coating a layer of semiconductor-type carbon nanotube thin film on a surface of SiOx or SiNx by a solution process (for example, spin-coating, dip-coating, etc.);

In the arrangement of the present disclosure, a method of solution process is used to manufacture a carbon nanotube thin film, and the solution process is a process for manufacturing a thin film at a low temperature by a solution method. In other arrangements, transfer print, vapor deposition or the like may also be employed.

The CNT may be prepared by a liquid phase method and a vapor phase method as an active layer in the TFT. In the liquid phase method, the prepared CNT is purified, dispersed in water or an organic solvent, and then formed on a desired substrate by dipping, spin coating, spraying, etc., and an active layer is formed by a patterning process. The CNT in the active layer formed on the base by the liquid phase method is generally a random network. The gas phase method may be used to directly manufacture CNT parallel arrays on a substrate.

Block 6: the channel pattern is defined through photolithography and then development, an oxygen reactive ion etching is performed by using a photoresist mask to remove the surrounding portion of carbon nanotubes to form a channel portion of the transistor, i.e., by using a mask plate to form a pattern and then to form an active layer.

Block 7: then, sequentially depositing, for example, MoO₃ having a thickness of 5-10 nm and, for example, Cu having a thickness of 200 nm (ranging from 2000 to 3000 angstroms) on the base substrate (the present disclosure is not limited thereto), and defining a source/drain pattern by photolithography and then development, thereafter preforming a wet etching process to complete patterning of the blocking layer and the source/drain;

Specifically, a source/drain conductive layer may be deposited by a sputtering method, and the source and the drain of the thin film transistor may be formed by a patterning process, and the source/drain conductive layer may be made of metal material such as Mo, Al, or Cr, alloy material, or other composite conductive material. In the exemplary arrangement, MoO₃ is used as a blocking layer. In other arrangements, other materials may be used as a blocking layer, such as an inorganic insulating layer of HfOx, SiNx, wherein a material, which only needs to satisfy that the top of valence band thereof is close to the top of valence band of the carbon nanotube and that the bottom of conduction band thereof is greatly different from the bottom of conduction band of the carbon nanotube, may be used as a blocking layer.

With the above blocks, the bottom gate thin film transistor of this arrangement may be manufactured.

Further, an array substrate according to the above thin film transistor may also be manufactured, and the method for manufacturing the array substrate further includes:

Block 8: depositing an insulating material such as silicon oxide and silicon nitride (SiNx) having a thickness of 300 nm by PECVD to form a surface passivation layer;

For example, SiOx can be deposited as a passivation layer at 370° C. by a CVD method; an organic material such as an acrylic material or a resin may also be used as the passivation layer.

Block 9: after photolithography and development, forming a via contact window of the source, the drain and the gate;

Block 10: depositing ITO having a thickness of for example 135 nm in the contact window by a sputtering process, and finally photolithographing, developing and etching it to form a final device.

Specifically, when the array substrate is an array substrate of a liquid crystal display (LCD), the electrode is a pixel electrode. In addition, the array substrate may further include a common electrode.

When the array substrate is an array substrate of an organic light-emitting diode (OLED) display, the electrode is an anode, and on the basis of this, the array substrate further includes a cathode and an organic material functional layer provided between the anode and the cathode.

An arrangement of the invention further provides a display panel including the above array substrate and an opposite substrate.

Specifically, when the array substrate is an array substrate of an LCD, the display panel may further include a color film substrate and a liquid crystal layer provided between the array substrate and the color film substrate.

When the array substrate is an array substrate of an OLED display, the display panel may further include a package substrate.

An arrangement of the present disclosure provides a display device including the array substrate of any one of the arrangements of the present disclosure, wherein the display device may be any product or component having a display function, such as a liquid crystal panel, a mobile phone, a tablet computer, a television, a display, a notebook computer, a digital photo frame, a navigator, or the like. Other indispensable components of the display device are neither those understood by those skilled in the art, and will not be described herein, nor should they be construed as limitation of the disclosure. The display device includes the above array substrate provided by the arrangement of the present disclosure. Since the principle for solving the problem of the display device is similar to that of the above array substrate, the implementation of the display device may refer to the implementation of the above array substrate, which will not be repeated.

The thin film transistor of the above arrangement is exemplified by a bottom gate structure, but the disclosure is not limited thereto, and may also be a top gate structure, an overlapped structure, an anti-overlapped structure, a coplanar structure or an anti-coplanar structure, or the like. The top gate structure is exemplified below.

FIG. 9 is a structural schematic view showing a seventh thin film transistor in an exemplary arrangement of the present disclosure.

As shown in FIG. 9, the thin film transistor may include: a base substrate 21, an active layer 24 provided on the base substrate 21, a blocking layer 25 provided on the active layer 24, a source 27 and a drain 26 provided on the blocking layer 25, a gate insulator 23 provided on the source 27 and the drain 26, and a gate 22 provided on the gate insulator 23.

In an exemplary arrangement, material of the blocking layer 25 may be V₂O₅. However, the present disclosure is not limited thereto, and any electron barrier material or hole barrier material may be used.

In the arrangement shown in FIG. 9, both the source 27 and the drain 26 are provided above the blocking layer 25, and the source 27 and the drain 26 completely cover the blocking layer.

FIG. 10 is a structural schematic view showing an eighth thin film transistor in an exemplary arrangement of the present disclosure.

In the arrangement shown in FIG. 10, it is different from the thin film transistor shown in FIG. 9 in that only the source 27 is provided above the blocking layer 25, i.e., the source 27 is not in direct contact with the active layer 24; the drain 26 is not provided above the blocking layer 25, i.e., the drain 26 is in direct contact with the active layer 24.

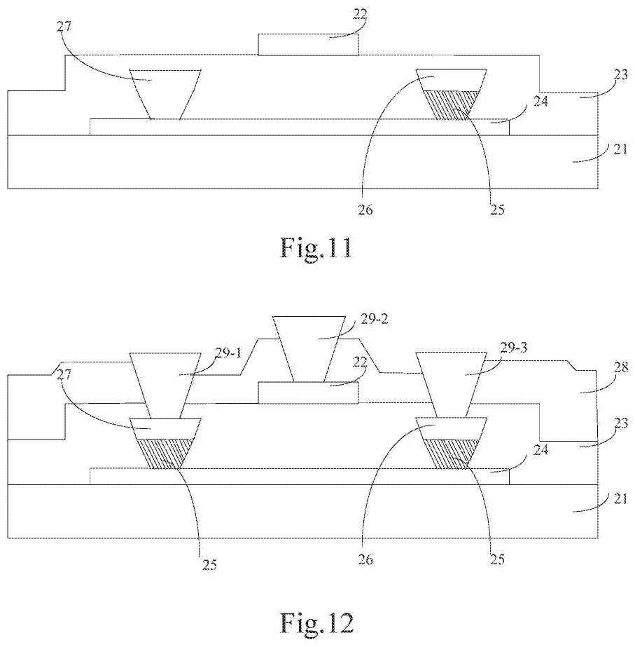

FIG. 11 is a structural schematic view showing a ninth thin film transistor in an exemplary arrangement of the present disclosure.

In the arrangement shown in FIG. 11, it is different from the thin film transistor shown in FIG. 9 in that the source 27 is in direct contact with the active layer 24, and a blocking layer 25 is disposed only between the drain 26 and the active layer 24.

It should be noted that although the above-described top gate structure only shows the arrangements shown in FIGS. 9-11, in fact, as long as an orthographic projection of the upper surface of the blocking layer on the base substrate is equal to or larger than an orthographic projection of the lower surface of the source and/or the drain on the base substrate 11 which is in contact therewith, it may be deformed referring to the above-described bottom gate structure, and will not be described in detail herein.

The present disclosure provides a structure of a carbon nanotube thin film transistor. By increasing an electron or hole barrier material between the source (or the drain) metal (or both the source metal and the drain metal) and the active layer, the off-state current is greatly reduced and the bipolar effect is suppressed. The method has the advantages of not changing the channel material, the stable performance and the simple process, etc.

FIG. 12 is a structural schematic view showing another array substrate corresponding to a structure of the thin film transistor shown in FIG. 9.

Further, an arrangement of the present disclosure further provides an array substrate, including the thin film transistor described in any of the above arrangements.

As shown in FIG. 12, the array substrate may further include a passivation layer 28, an electrode (e.g., ITO) 29-1 disposed above the source 27, an electrode 29-2 disposed above the gate 22, and an electrode 29-3 disposed above the drain 26.

Hereinafter, a method for manufacturing a top gate carbon nanotube thin film transistor with V₂O₅ having a thickness of 5-10 nm as a blocking layer on a glass substrate will be described as an example.

Block 1: cleaning, for example, a glass substrate according to a standard method.

Wherein, first providing a base substrate, which may be a glass substrate, a quartz substrate or the like.

Block 2: depositing a layer of, for example, a semiconductor-type carbon nanotube thin film on the obtained glass substrate by dip coating, spin coating or the like.

Block 3: after photolithography and development, for example, oxygen reactive ion etching is performed by using a photoresist mask to remove the surrounding portion of carbon nanotubes to form a channel portion of the transistor.

Block 4: then, depositing, for example, V₂O₅ having a thickness of 5-10 nm and, for example, Cu (or Ni) having a thickness of 200 nm on the glass substrate, thereafter performing photolithography and development, performing an etching process to complete patterning of the source/drain.

In the exemplary arrangement, V₂O₅ is taken as a blocking layer. In other arrangements, other materials may be used as a blocking layer, such as an inorganic insulating layer of HfOx, SiNx, wherein a material, which only needs to satisfy that the top of valence band thereof is close to the top of valence band of the carbon nanotube and that the bottom of conduction band thereof is greatly different from the bottom of conduction band of the carbon nanotube, may be used as a blocking layer.

Block 5: depositing an insulating material such as SiOx having a thickness of 100 nm by a PECVD method to form a gate insulator.

Forming the gate insulator may specifically include: forming a gate insulating thin film on the base substrate on which the active layer is formed, and forming a via hole through the gate insulating thin film and the semiconductor layer by a patterning process to form a gate insulator.

Block 6: depositing a gate metal such as Mo having a thickness of 220 nm by sputtering, and then photolithographing, developing and etching it to realize the patterning of the gate.

Wherein, material of the gate, the source and the drain may be a combination of one or more of Pd (palladium), Ti (titanium), Al (aluminum), Cr (chromium), Au (gold), Pt (platinum), TiN (titanium nitride) or TaN (tantalum nitride) or the like.

With the above blocks, the top gate thin film transistor of this arrangement can be manufactured.

Further, the method for manufacturing the array substrate may further include:

Block 7: depositing an insulating material such as SiNx having a thickness of 300 nm (ranging from 3000 to 4000 angstroms) by PECVD to form a surface passivation layer.

Block 8: after photolithography and development, forming a via contact window of the source, the drain and the gate, in order to conduct electricity for connecting the ITO to each of electrodes.

Block 9: depositing such as ITO having a thickness of 135 nm in the contact window by a sputtering process, and finally photolithographing, developing and etching it to form a final device.

Further, when the array substrate is an LCD array substrate, the subsequent manufacturing process may further include PT coating, imprint orientation, spacer manufacturing, and manufacturing of a corresponding color film substrate, and other processes such as paired-boxing, cutting and sealing, which will not be repeated below.

In this arrangement, after deposition of the CNT material, a doping and activation process may be performed as needed; and an etch blocking layer may be formed to protect the active layer before depositing the conductive layer.

In the arrangement of the present disclosure, the off-state current is greatly reduced and the bipolar effect is suppressed by adding an electron or a hole barrier material between the source (or the drain) metal (or both the source metal and the drain metal) and the active layer, thus improving the display.

Other arrangements of the present disclosure will be apparent to those skilled in the art after reading the specification and implementing the invention disclosed herein. The present application is intended to cover any variations, purposes, or adaptations of the present disclosure, which are in accordance with the general principles of the present disclosure and include common general knowledge or conventional technical means in the art that are not disclosed in the present disclosure. The specification and arrangements are to be regarded as illustrative only, and the real scope and spirit of the present disclosure is defined by the attached claims.

1. A thin film transistor comprising a source, a drain and an active layer, wherein the thin film transistor further comprises: a blocking layer provided between the active layer and at least one of the source or the drain.

2. The thin film transistor according to claim 1, wherein the at least one of the source or the drain is provided above the blocking layer, and at least one of the source or drain cover the blocking layer.

3. The thin film transistor according to claim 1, wherein the blocking layer comprises an electron blocking layer or a hole blocking layer, and wherein the electron blocking layer is made of electron barrier material, and the hole blocking layer is made of hole barrier material.

4. The thin film transistor according to claim 3, wherein the active layer comprises a carbon nanotube, and a top of valence band of the electron barrier material is equal to a top of valence band of the carbon nanotube, and a bottom of conduction band of the electron barrier material and a bottom of conduction band of the carbon nanotube differ by a predetermined value.

5. The thin film transistor according to claim 1, wherein the thin film transistor comprises:
a base substrate;
a gate of the thin film transistor provided on the base substrate; and
a gate insulator covering the gate;
wherein the active layer is provided on the gate insulator;
the blocking layer is provided on the active layer; and
the at least one of the source or the drain is provided on the blocking layer.

6. The thin film transistor according to claim 5, wherein a material of the blocking layer is MoO₃.

7. The thin film transistor according to claim 1, wherein the thin film transistor comprises:
a base substrate;
a gate insulator provided on the source and the drain; and
a gate provided on the gate insulator;
wherein the active layer provided on the base substrate;
the blocking layer is provided on the active layer; and
the at least one of the source or the drain are provided on the blocking layer.

8. The thin film transistor according to claim 7, wherein a material of the blocking layer is V₂O₅.

9. The thin film transistor of claim 1, wherein the source and the drain comprise metal.

10. An array substrate comprising a thin film transistor comprising:
a source, a drain and an active layer, wherein the thin film transistor further comprises: a blocking layer provided between the active layer and at least one of the source or the drain.

11. The array substrate according to claim 10, wherein the at least one of the source or the drain are provided above the blocking layer, and the at least one of the source or drain cover the blocking layer.

12. The array substrate according to claim 10, wherein the blocking layer comprises an electron blocking layer or a hole blocking layer, and wherein the electron blocking layer is made of electron barrier material, and the hole blocking layer is made of hole barrier material.

13. The array substrate according to claim 12, wherein the active layer comprises a carbon nanotube, and a top of valence band of the electron barrier material is equal to a top of valence band of the carbon nanotube, and a bottom of conduction band of the electron barrier material and a bottom of conduction band of the carbon nanotube differ by a predetermined value.

14. The array substrate according to claim 10, wherein the thin film transistor comprises:
a base substrate;
a gate of the thin film transistor provided on the base substrate; and
a gate insulator covering the gate;
wherein the active layer is provided on the gate insulator;
the blocking layer is provided on the active layer; and
the at least one of the source or the drain are provided on the blocking layer.

15. The array substrate according to claim 14, wherein a material of the blocking layer is MoO₃.

16. The array substrate according to claim 10, wherein the thin film transistor comprises:
a base substrate;
a gate insulator provided on the source and the drain; and
a gate provided on the gate insulator;
wherein the active layer is provided on the base substrate;
the blocking layer is provided on the active layer; and
the at least one of the source or the drain are provided on the blocking layer.

17. The array substrate according to claim 16, wherein a material of the blocking layer is V₂O₅.

18. The array substrate of claim 10, wherein the source and the drain comprise metal.
